(19) United States
(12) Patent Application Publication
(10) Pub. No.: US 2021/0391515 A1
(43) Pub. Date: Dec. 16, 2021

(54) LIGHT - EMITTER - MOUNTED SUBSTRATE AND BACKLIGHT

(71) Applicant: SHARP KABUSHIKI KAISHA, Osaka (JP)

(72) Inventor: HISASHI WATANABE, Osaka (JP)

(21) Appl. No.: 17/328,489

(22) Filed: May 24, 2021

Related U.S. Application Data
(60) Provisional application No. 63/037,391, filed on Jun. 10, 2020.

(51) Int. Cl. H01L 33/60; H01L 33/56; H01L 33/48; H01L 25/075; G02F 1/13357

(52) U.S. Cl. CPC H01L 33/60; H01L 33/56; G02F 1/133605; H01L 25/0753; G02F 1/133603; H01L 33/486

(57) ABSTRACT

A tight-emitter-mounted substrate includes a circuit board, and a light emitter disposed on the circuit board. The light emitter has an electrode and an emission part. The electrode is electrically connected to the circuit board. The emission part emits light in accordance with a voltage applied via the electrode. The light-emitter-mounted substrate also includes a reflector facing an emission surface of the emission part. The reflector reflects the light emitted from the emission part. The light-emitter-mounted substrate also includes a transparent layer covering the Hot emitter and reflector on the circuit board. The transparent layer has light transparency.

### CROSS-REFERENCE TO RELATED APPLICATION

The present application claims priority to U.S. Provisional Application Ser. No. 63/037,391, filed Jun. 10, 2020. the content to which is hereby incorporated by reference into this application.

### BACKGROUND

### 1. Field

The present disclosure relates to a light-emitter-mounted substrate and a backlight,

### 2. Description of the Related Art

For instance, Japanese Patent Application Laid-Open No. 2007-53352 discloses a light-emitting-diode light source used for the backlight of a liquid crystal display. The backlight has light emitting diodes (LEDs), one example of light emitters, and a circuit board on which circuit wires electrically connected to the LEDs are printed. The circuit board has a main surface, on which a transparent protective layer covers the LEDs and circuit wires. The protective layer protects the LEDs.

Disposed immediately above the LEDs covered with the protective layer are reflectors. The reflectors are shaped in conformance with the LEDs and have a reflectivity of 95% or more.

### SUMMARY

Unfortunately, the LED light source disclosed in Patent Literature I involves brightness unevenness in its emission surface. The present disclosure has been made to solve this problem. It is an object of the present disclosure to provide a light-emitter-mounted substrate and backlight that can prevent brightness unevenness in its emission surface.

### Solution to Problem

(1) A light-emitter-mounted substrate in the present disclosure includes the following: a circuit board; a light emitter disposed on the circuit board, the light emitter having an electrode and an emission part, the electrode being electrically connected to the circuit board, the emission part being designed to emit light in accordance with a voltage applied via the electrode; a reflector facing an emission surface of the emission part, the reflector being designed to reflect the light emitted from the emission part; and a transparent layer covering the light emitter and the reflector on the circuit board, the transparent layer having light transparency.

(2) In the light-emitter-mounted substrate according to Aspect (1) of the present disclosure, the transparent layer includes a first transparent layer covering the light emitter, and a second transparent layer disposed on the first transparent layer and covering the reflector,

(3) in the light-emitter-mounted substrate according to Aspect (2) of the present disclosure, the light emitter is a light-emitter package including a transparent sealing layer sealing the emission part. The transparent sealing layer is the first transparent layer. In addition, the reflector is disposed on the light-emitter package. In addition, the second transparent layer covers the light-emitter package and the reflector on the circuit board,

(4) In the light-emitter-mounted substrate according to Aspect (2) of the present disclosure, the light emitter is a light-emitter bare chip with the electrode being in contact with the circuit board to establish electrical connection. The light-emitter bare chip includes a transparent substrate having a main surface on which the emission part and the electrode are disposed. The transparent substrate is the first transparent layer. In addition, the reflector is disposed on a surface opposite to the main surface of the transparent substrate. In addition, the second transparent. layer covers the light-emitter bare chip and the reflector on the circuit board.

(5) In the light-emitter-mounted substrate according to any one of Aspects (2) to (4) of the present disclosure, the second transparent layer has a refractive index equal to or higher than the refractive index of the first transparent layer.

(6) The light-emitter-mounted substrate according to any one of Aspects (1) to (5) of the present disclosure includes a partition wall surrounding the light emitter on the circuit board in a plan view of the light-emitter-mounted substrate. The partition wall is composed of a high-reflectivity member.

(7) In the light-emitter-mounted substrate according to any one of Aspects (1) to (6) of the present disclosure, the reflector overlaps the light emitter in a plan view of the light-emitter-mounted substrate. In addition, the diagonal line of the planar shape of the reflector has a length ranging from to 10L inclusive. Herein, L is the length of the diagonal line of the planar shape of the light emitter.

(8) In the light-emitter-mounted substrate according to Aspect (7) of the present disclosure, the planar shape of each of the light emitter and the reflector is rectangular or circular in the plan view of the tight-emitter-mounted substrate.

(9) In the light-emitter-mounted substrate according to Aspect (8) of the present disclosure, the planar shape of the light emitter is rectangular, and the planar shape of the reflector is circular,

(10) In the light-emitter-mounted substrate according to Aspect (8) of the present disclosure, the planar shape of each of the light emitter and the reflector is rectangular,

(11) In the light-emitter-mounted substrate according to Aspect (8) of the present disclosure, the planar shape of the light emitter and the planar shape of the reflector are similar.

(12) In the light-emitter-mounted substrate according to any one of Aspects (1) to (11) of the present disclosure, the transparent layer is thicker than the light emitter, and is 10 times or less as thick as the light emitter.

(13) A backlight in the present disclosure includes the light-emitter-mounted substrate according to any one of Aspects (1) to (12). The backlight also includes a frame having a bottom surface on which the light-emitter-mounted substrate is disposed, and having a sidewall surrounding the light-emitter-mounted substrate around the perimeter of the bottom surface. The backlight also includes an optical sheet retained by the sidewall. The optical sheet is designed to change the light emitted from the emission part into a planar light source.

### BRIEF DESCRIPTION OF DRAWINGS

FIG. 1 is a schematic plan view of an example backlight according to a first preferred embodiment of the present disclosure;

FIG. 2 is a sectional view of the backlight taken along line 1141 in FIG. 1,

FIG. 3 is a sectional view of an example configuration of a light emitter mounted on a circuit board of a light-emitter-mounted substrate included in a backlight according to the first preferred embodiment of the present disclosure;

FIG. 4 is a sectional view of an example configuration of the light emitter mounted on the circuit board of the light-emitter-mounted substrate, included in the backlight according to the first preferred embodiment of the present disclosure;

FIG. 5 is a schematic plan view of an example of the backlight according to the first preferred embodiment of the present disclosure;

FIG. 6 schematically illustrates an example optical path in the backlight according to the first preferred embodiment of the present disclosure;

FIG. 7 schematically illustrates an example optical path in a backlight according to a comparative example of the first preferred embodiment of the present disclosure;

FIG. 8 schematically illustrates light diffusion in an example where a transparent layer in the backlight according to the first preferred embodiment of the present disclosure has a thickness d1;

FIG. 9 schematically illustrates light diffusion in an example where the transparent layer in the backlight according to the first preferred embodiment of the present disclosure has a thickness d2;

FIG. 10 illustrates an example process step for forming the light-emitter-mounted substrate, included in the backlight according to the first preferred embodiment of the present disclosure;

FIG. 11 illustrates an example process step for forming the light-emitter-mounted substrate, included in the backlight according to the first preferred embodiment of the present disclosure;

FIG. 12 illustrates an example process step for forming the light-emitter-mounted substrate, included in the backlight according to the first preferred embodiment of the present disclosure;

FIG. 13 illustrates an example process step for forming the light-emitter-mounted substrate, included in the backlight according to the first preferred embodiment of the present disclosure;

FIG. 14 is a sectional view of an example, modified version of the backlight according to the first preferred embodiment of the present disclosure;

FIG. 15 is a sectional view of an example backlight according to a second preferred embodiment of the present disclosure;

FIG. 16 schematically illustrates an example configuration of a light emitter mounted on a light-emitter-mounted substrate included in the backlight according to the second preferred embodiment of the present disclosure;

FIG. 17 schematically illustrates an example configuration of a light emitter mounted on a light-emitter-mounted substrate included in a backlight according to a modification of the second preferred embodiment of the present disclosure;

FIG. 18 schematically illustrates an example step of forming the light-emitter-mounted substrate, included in the backlight according to the modification of the second preferred embodiment of the present disclosure;

FIG. 19 schematically illustrates an example step of forming the light-emitter-mounted substrate, included in the backlight according to the modification of the second preferred embodiment of the present disclosure;

FIG. 20 is a schematic plan view of an example configuration of a backlight according to a third preferred embodiment;

FIG. 21 is a sectional view of the backlight according to the third preferred embodiment, taken along line

FIG. 22 schematically illustrates an example optical path in a light-emitter-mounted substrate included in the backlight according to the third preferred embodiment; and

FIG. 23 schematically illustrates an example optical path in a light-emitter-mounted substrate included in a backlight according to a comparative example of the third preferred embodiment.

### DETAILED DESCRIPTION

With reference to the drawings, the following describes the configuration of a backlight 100 including a light-emitter-mounted substrate 50 according to preferred embodiments of the present disclosure. Identical or equivalent components will be denoted by the same signs throughout the drawings, and redundancies will not be elaborated.

### First Preferred Embodiment

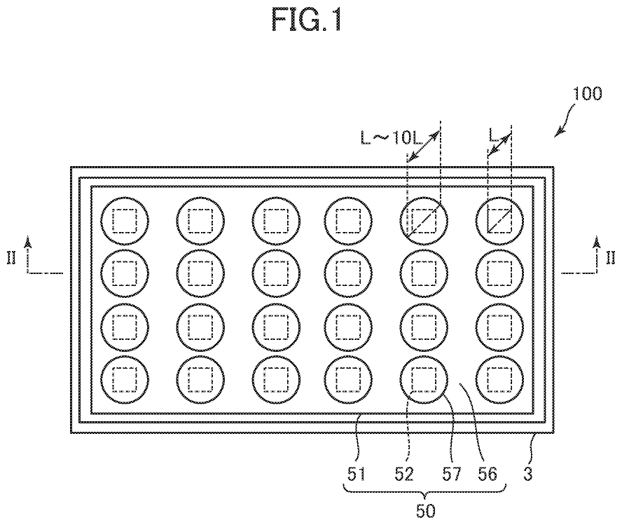

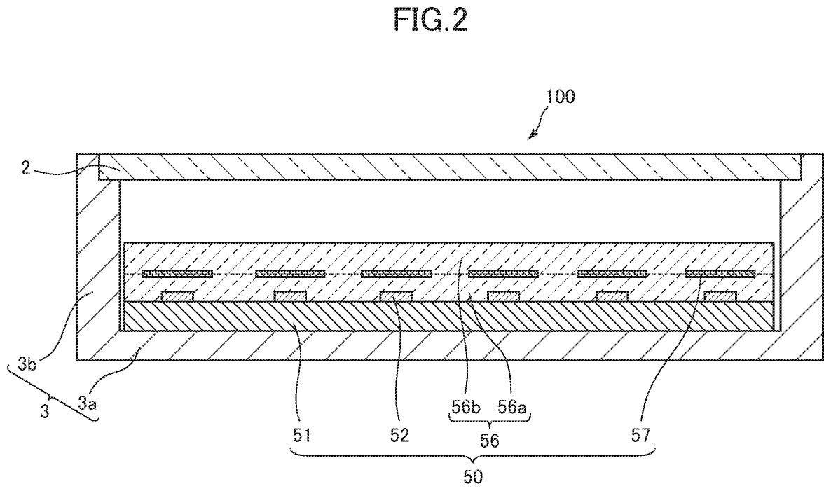

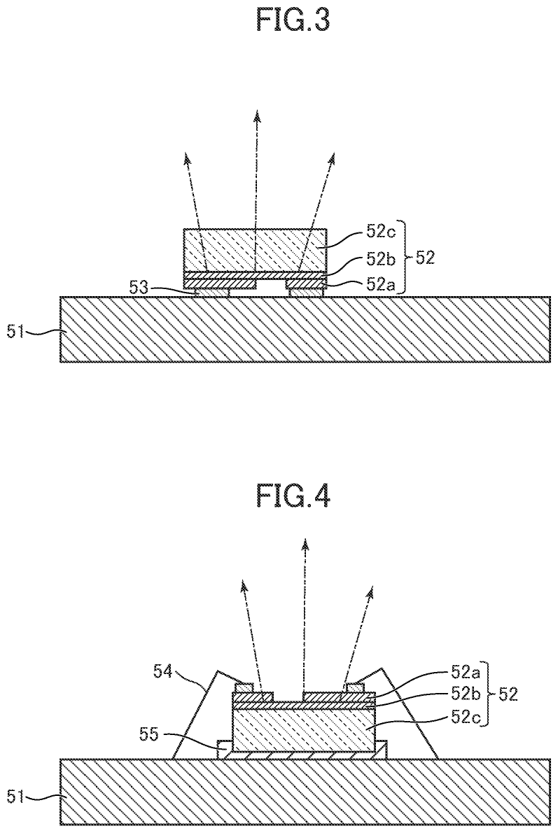

The backlight 100 including the light-emitter-mounted substrate 50 according to a first preferred embodiment of the present disclosure will be described with reference to FIGS. 1 to 4. FIG. 1 is a schematic plan view of one example of the backlight 100 according to the first preferred embodiment of the present disclosure. FIG. 2 is a sectional view of the backlight 100 taken along line II-II in FIG. 1, FIGS. 3 and 4 are sectional views of example configurations of a light emitter 52 mounted on a circuit board 51, included in the light-emitter-mounted substrate 50 of the backlight 100 according to the first preferred embodiment of the present disclosure. In FIG. 2, where the light-emitter-mounted substrate 50 is disposed is the lower part of the backlight 100, and the direction where light from the backlight 100 exits is the upper part of the backlight 100.

The backlight 100 according to the first preferred embodiment is a direct-lit backlight for instance, which is placed on the backside of a display device, such as a liquid crystal display. The backlight 100 includes the light-emitter-mounted substrate 50, a frame 3 housing the light-emitter-mounted substrate 50, and an optical sheet 2, as illustrated in FIGS. 1 and 2.

The optical sheet 2, an optical member, changes light emitted by the light emitter 52 (described later on) into a uniform, planar light source to generate uniform light. The optical sheet 2 has a surface constituting the emission surface of the backlight 100. The optical sheet 2 is a laminate consisting of, in combination as necessary, a diffuser plate, a diffuser sheet, a prism sheet and a polarization-reflecting layer sheet. For instance, the optical sheet 2 can be formed by laminating a diffuser plate, a diffuser sheet, a first prism sheet, a second prism sheet, and a polarization-reflecting layer sheet in this order from the bottom toward the top.

An example of the diffuser plate usable herein is a SUMIPEX (registered trademark) opal plate made by SUMITOMO CHEMICAL Another example of the diffuser sheet usable is D114 (article name) made by TSUJIDEN. This diffuser plate or diffuser sheet can diffuse light, thus making a light source (light emitter 52) less visible.

An example of the prism sheet usable is an optical film, such as BEF (article name) made by 3M. This prism sheet can concentrate light emitted by the light emitter 52, thus improving brightness.

An example of the polarization-reflecting layer sheet usable is a reflective polarizer film such as DBEF (article name) made by 3M. This polarization-reflecting layer sheet can prevent the polarizer plate of a liquid crystal panel (not shown) from absorbing light emitted from the backlight 100 toward the liquid crystal panel. The polarization-reflecting layer sheet, which can prevent the polarizer plate from absorbing light, can improve light usage.

The frame 3 retains the optical sheet 2 and houses the light-emitter-mounted substrate 50, as illustrated in FIG. 2. The frame 3 is made of a high-reflectivity resin or other materials. An example of the high-reflectivity resin is white polycarbonate.

To be specific, the frame 3 has a bottom surface 3a on which the light-emitter-mounted substrate 50 is disposed, and the frame 3 has a sidewall 3b surrounding the light-emitter-mounted substrate 50 around the perimeter of the bottom surface 3a. The sidewall 3b has a proximal end on the bottom surface 3a, and has a distal end opposite the proximal end. The frame 3 retains the optical sheet 2 at the distal end of the sidewall 3b. As described, the light-emitter-mounted substrate 50 is housed in a space defined by the frame 3 and optical sheet 2.

The light-emitter-mounted substrate 50 includes the circuit board 51, a plurality of light emitters 52, a plurality of reflectors 57, and a transparent layer 56.

The circuit board 51 has a main surface on which circuit wires (not shown) are printed. The main surface is provided with a plurality of electrode pads (not shown) electrically connected to the circuit wires. The circuit wires are electrically connected to a power source (not shown) via cables (not shown). The circuit board 51 contains glass epoxy, polyimide, or aluminum as its base material.

Each light emitter 52 is an LED bare chip (light-emitter bare chip). The light emitters 52 are arranged in matrix on the main surface of the circuit board 51 at predetermined intervals, as illustrated in FIG. 1. The color of light emitted by the light emitters 52 can be designed freely; white is preferable. Alternatively, three colors of LED bare chips: an LED bare chip of R (red), an LED bare chip of G (green), and an LED bare chip of B (blue) may be arranged at predetermined intervals.

The light emitters 52 are electrically connected to the circuit board 51 via the respective electrode pads. Each light emitter 52 is supplied with current from the power source via the corresponding cable and circuit wire. As described, the backlight 100 is designed to control the power source to supply a particular current to each light emitter 52. It is noted that the electrodes pads are coated with white resist ink (e.g., PSR-4000 made by TAIYO INK) for reflectivity enhancement.

As illustrated in FIG. 3, each light emitter 52 has an electrode 52a electrically connected to the circuit board 51, and has an emission part 52b that emits light in accordance with a voltage applied via the electrode 52a. The light emitters 52 are mounted onto the circuit board 51 through flip-chip mounting, as illustrated in FIG. 3.

That is, each light emitter 52 is configured such that the emission part 52b in the form of a layer is disposed on a transparent substrate 52c, such as a sapphire substrate, and such that the electrode 52a is disposed on the emission part 52b, which constitutes the upper surface of the light emitter 52. Mounting the light emitter 52 onto the circuit board 51 requires turning the upper surface of the light emitter 52 upside down (face-down), followed by joining the electrode 52a to the circuit board 51 with solder 53. The light emitter 52 turned upside down in this way is electrically and physically joined to the circuit board 51 with the solder 53,

Each light emitter 52 is mounted onto the circuit board 51 through any method other than flip-chip mounting. For instance, the electrode 52a may be electrically joined to the circuit board 51 via a wire 54 with the upper surface of the light emitter 52 not being turned upside down (face-up), as illustrated in FIG. 4. When the light emitter 52 in this face-up condition is mounted onto the circuit board 51, the light emitter 52 is physically joined to the circuit board 51 with a silver paste 55.

Each reflector 57 faces the emission surface of the emission part 52b above the light emitter 52. In other words, each reflector 57 overlaps the emission part 52b above the light emitter 52 in a plan view of the light-emitter-mounted substrate 50. The reflector 57 reflects light emitted by the emission part 52b. The reflector 57 is a regular reflector or diffusion reflector having a reflectivity of 95% or more, preferably 97% or more. The reflector 57 is composed of a material having high reflectivity and low light-absorbing capability. For instance, the reflector 57 can be composed of a thin film of metal, such as aluminum, silver, platinum, or alloy of these metals. Alternatively, the reflector 57 may be composed of white resist ink.

In a plan view of the light-emitter-mounted substrate 50, the planar shape of each reflector 57 is circular, and the planar shape of each light emitter 52 is rectangular (square), as illustrated ire FIG. 1. The following dimensional relationship is established between the planar shape of the reflector 57 and the planar shape of the light emitter 52. That is, let the diagonal line of the planar shape of the light emitter 52 have a length of L; accordingly, the planar shape of the reflector 57 has a length in diameter ranging from L to 10L inclusive, preferably from L to 3L inclusive, further preferably from L to 2L inclusive. The dimension of the reflector 57 is set as appropriate, by reflecting the distribution of illumination in a virtual plane that is parallel to the main surface of the circuit board 51 and includes the reflector 57.

The reflector 57, which is disposed above the light emitter 52, can reflect light emitted upward from the emission part 52b. As such, the backlight 100 including the light-emitter-mounted substrate 50 with the plurality of light emitters 52 thereon is configured such that each light emitter 52 is bright immediately above, and that the region between the light emitter 52 and adjacent light emitter 52 is dark. This configuration can prevent brightness unevenness in the emission surface of the backlight 100.

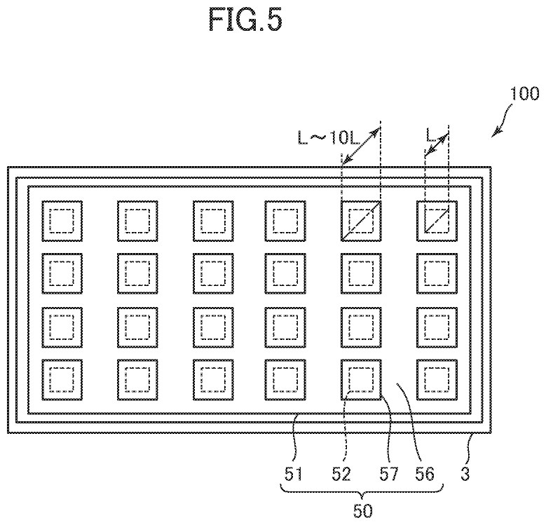

In the foregoing, the planar shape of the light emitter 52 is rectangular, and the planar shape of the reflector 57 is circular. In some preferred embodiments, both the planar shape of the light emitter 52 and the planar shape of the reflector 57 may be rectangular, as illustrated ins FIG. 5. FIG. 5 is a schematic plan view of an example of the backlight 100 according to the first preferred embodiment of the present disclosure.

The planar shape of each of the light emitter 52 and reflector 57 may be rectangular, as described above. Here, let the diagonal line of the planar shape of the light emitter 52 have a length of L; accordingly, the diagonal line of the planar shape of the reflector 57 has a length ranging from L to 10L inclusive, preferably from L to 3L inclusive, further preferably from L to 2L inclusive. In some preferred embodiments, the planar shape of the light emitter 52 and the planar shape of the reflector 57 may be similar to each other.

The light-emitter-mounted substrate 50 according to the present disclosure includes the transparent layer 56 covering the light emitters 52 and reflectors 57 on the circuit board 51, as illustrated in FIG. 2. The transparent layer 56 has light transparency. The transparent layer 56 can be formed by applying, onto the circuit board 51, a transparent resin having light transparency and low tight-absorbing capability, such as acrylic resin, epoxy resin, silicone resin, or urethane resin. The transparent layer 56 is formed through, for instance, slit coating, screen printing, or inkjet printing. The transparent layer 56 may be an adhesive layer disposed on a transparent base material (e.g., PET or polyethylene terephthalate) and having light transparency; such as an acrylic adhesive layer, an epoxy adhesive layer, a silicone adhesive layer, or a urethane adhesive layer. Alternatively, the transparent layer 56 may be a bonding layer that is composed of a transparent optical adhesive sheet (e.g., an OCA or optical clear adhesive) transferred on the circuit board 51.

When the light-emitter-mounted substrate 50 including the reflectors 57 has a small amount of light guided above each reflector 57, light emitted from a location where the reflector 57 is not placed is brighter than light emitted from a location where the reflector 57 is placed. This unfortunately causes brightness unevenness in the emission surface of the backlight 100. Accordingly, the light-emitter-mounted substrate 50 according to the first preferred embodiment of the present disclosure includes the transparent layer 56, which covers the light emitters 52 and reflectors 57. The light-emitter-mounted substrate 50 is designed to guide light emitted by the emission part 52b to a location above each reflector 57 through the transparent layer 56, thus allowing the light to go outside.

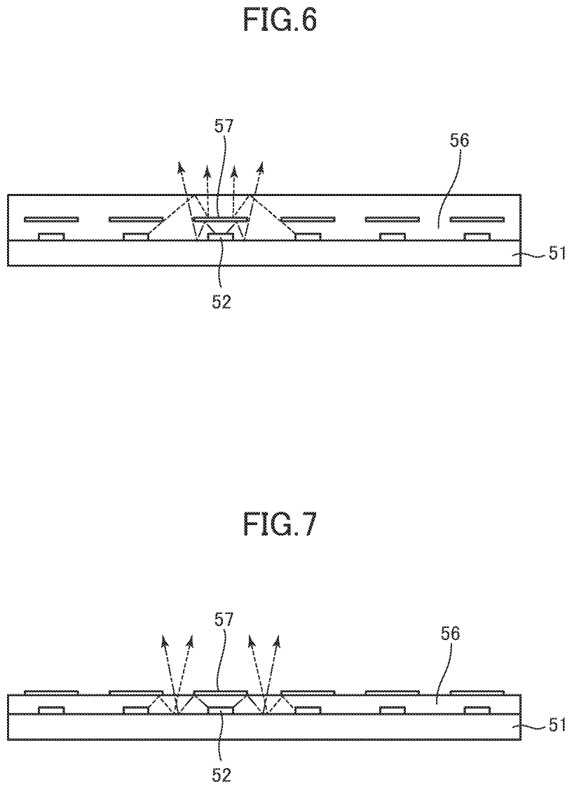

With reference to FIGS. 6 and 7, the following specifically describes effects obtained by the transparent layer 56 covering the light emitters 52 and reflectors 57. FIG. 6 schematically illustrates an example optical path in the backlight 100 according to the first preferred embodiment of the present disclosure. FIG. 7 schematically illustrates an example optical path in a backlight according to a comparative example of the first preferred embodiment of the present disclosure. In FIGS. 6 and 7, the optical path of light emitted from one light emitter 52 is denoted by dot-dashed lines, and the optical path of light emitted from another light emitter 52 adjacent to the one light emitter 52 is denoted by broken lines,

As illustrated in FIG. 6, the light-emitter-mounted substrate 50 in the backlight 100 according to the first preferred embodiment of the present disclosure guides, through the transparent layer 56 to a location above the reflector 57 facing one light emitter 52, light emitted from another light emitter 52 adjacent to the one light emitter 52. For instance, among the light beams emitted by the other adjacent light emitter 52, light that passes through the transparent layer 56 without being reflected by the corresponding reflector 57 facing the other light emitter 52 is guided. In addition, light that passes through without being reflected by the other reflector 57 and reflects on the interface between the transparent layer 56 and air is also guided. Consequently, the backlight 100 according to the first preferred embodiment can prevent brightness unevenness in its emission surface.

In contrast, the comparative backlight has a light-emitter-mounted substrate on which the transparent layer 56 does not cover the plurality of reflectors 57, as illustrated in FIG. 7. Hence, light from one light emitter 52 is little guided above the reflector 57 facing another light emitter 52 adjacent to the one light emitter 52. This produces a brightness difference between light exiting out of a location where the reflector 57 is disposed and light exiting out of a location where the reflector 57 is not disposed. Consequently, the backlight possibly has brightness unevenness in its emission surface.

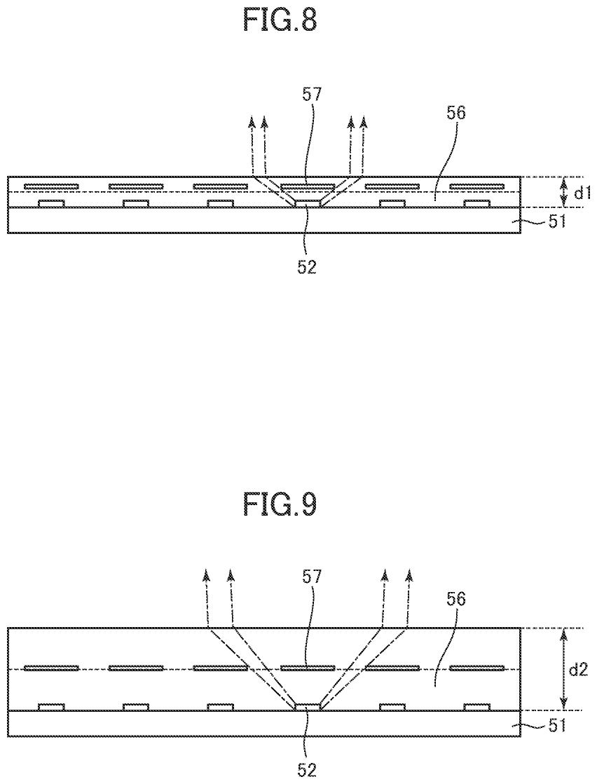

In addition, different thicknesses of the transparent layer 56 measured from the circuit board 51 involve different capabilities of diffusion of light emitted from the light emitter 52 even when the transparent layer 56 covers the light emitters 52 and reflectors 57. Let a thickness d1<a thickness d2 be established for instance, as illustrated in FIGS. 8 and 9. Accordingly, the transparent layer 56 with the thickness d2 tends to have a larger capability of light diffusion than the transparent layer 56 with the thickness d 1. FIG. 8 schematically illustrates light diffusion in an example where the transparent layer 56 in the backlight 100 according to the first preferred embodiment of the present disclosure has the thickness di. FIG. 9 schematically illustrates light diffusion in an example where the transparent layer 56 in the backlight 100 according to the first preferred embodiment of the present disclosure has the thickness d. In FIGS. 8 and 9, the optical path of light emitted from the light emitter 52 is denoted by broken lines.

Brightness uniformity in the emission surface of the backlight 100 can improve along with increase in the thickness of the transparent layer 56, thereby preventing brightness unevenness. However, an excessive increase in the thickness of the transparent layer 56 makes it difficult to form the transparent layer 56 uniformly. Furthermore, the transparent layer 56 contracts in some cases after it is stacked onto the circuit board 51. In such a contraction, the transparent layer 56 warps more greatly along with increase in thickness, highly probably peeling off from the circuit board 51.

Accordingly, the backlight 100 according to the first preferred embodiment is configured such that the transparent layer 56 is thicker than the light emitters 52, and is 10 times or less as thick as the light emitters 52. Each light emitter 52 according to the first preferred embodiment is an LED bare chip and is about 0.1 mm thick. Hence, the transparent layer 56 preferably has a thickness that is greater than 0.1 mm and 1 mm or less, in particular, a thickness of 1 mm.

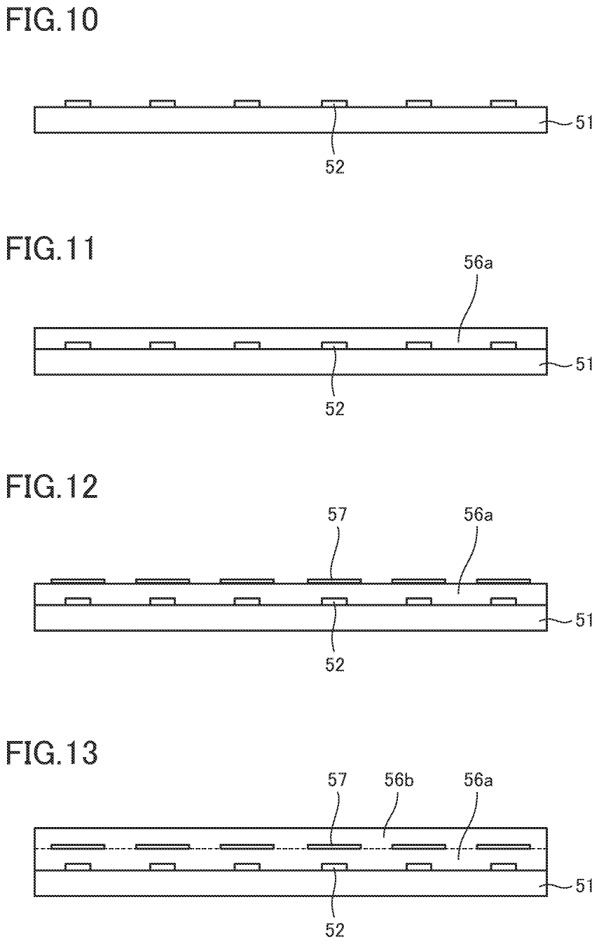

With reference to FIGS. 10 to 13, the following describes how to form the light-emitter-mounted substrate 50 of the backlight 100. FIGS. 10 to 13 illustrate example process steps for forming the light-emitter-mounted substrate 50 of the backlight 100 according to the first preferred embodiment of the present disclosure.

Process Steps for Forming Light-Emitter-Mounted Substrate

Firstly, the circuit board 51 is placed onto the bottom surface 3a of the frame 3. The plurality of emitters 52 are then arranged in matrix onto the circuit board 51 at predetermined intervals and are then mounted onto the circuit board 51, as illustrated in FIG. 10. Mounting the light emitters 52 onto the circuit board 51 uses flip-chip mounting, as earlier described. Alternatively, mounting the light emitters 52 onto the circuit board 51 may be performed by electrically joining the electrodes 52a to the circuit board 51 via the wires 54 with the light emitters 52 facing up.

Mounting the light emitters 52 onto the circuit board 51 in the foregoing manner is followed by, as illustrated in FIG. 11, stacking a first transparent layer 56a onto the circuit board 51 so as to cover the light emitters 52. Stacking the first transparent layer 56a can use screen printing or ink-jet printing, as earlier described, or can use spray application or other methods.

Thereafter, as illustrated in FIG. 12, the plurality of reflectors 57 are formed onto the first transparent layer 56a so as to face the respective light emitters 52, that is, so as to overlap the respective light emitters 52 in a plan view of the light-emitter-mounted substrate 50. The reflectors 57 can be formed through evaporation or plating, or through screen printing or inkjet printing, fir instance.

Furthermore, a second transparent layer 56b is stacked onto the first transparent layer 56a so as to cover the reflectors 57, as illustrated in FIG. 13. Like the first transparent layer 56a, stacking the second transparent layer 56b can use screen printing or inkjet printing, as earlier described, or can use spray application or other methods.

It is noted that the first transparent layer 56a and the second transparent layer 56b preferably establish a thickness relationship of one-to-one. The second transparent layer 56b has the same refractive index as the first transparent layer 56a. The same refractive index between the first transparent layer 56a and second transparent layer 56b can avoid refraction of light impinging on the interface between the first transparent layer 56a and second transparent layer 56b. Alternatively, the second transparent layer 56b may have a higher refractive index than the first transparent layer 56a. The second transparent layer 56b that has a higher refractive index than the first transparent layer 56a offers, without total reflection, efficient propagation of light impinging on the interface between the first transparent layer 56a and second transparent layer 56b. Furthermore, such a higher refractive index offers total reflection at the interface between the first transparent layer 56a and second transparent layer 56b even when light once impinging on the second transparent layer 56b partly reflects to travel toward the first transparent layer 56a. This can reduce the ratio of light that returns from the second transparent layer 56b to the first transparent layer 56a and is then absorbed by an absorber, such as a wire.

As such, the second transparent layer 56b has a refractive index equal to or higher than the refractive index of the first transparent layer 56a. This enables light passing through the first transparent layer 56a to be guided to the second transparent layer 56b properly.

Each light emitter 52 of the light-emitter-mounted substrate 50 in an LED bare chip. However, the light emitter 52 is not limited to an LED bare chip. The light emitter 52 may be an LED package (light-emitter package) with an LED bar-chip packaged.

An LED package as the light emitter 52 is easier to mount onto the light-emitter-mounted substrate 50 than an LED bare chip as the light emitter 52. However, an LED package as the light emitter 52 is 0.5 mm thick, whereas an LED bare chip as the light emitter 52 is 0.1 mm thick. When the light emitter 52 is an LED package, the first transparent layer 56a is thicker than that of an LED bare chip being the light emitter 52; so is the thickness of the second transparent layer 56b.

Moreover, along with increase in the thickness of a member that is mounted onto the circuit board 51, the first transparent layer 56a covering this member highly probably has asperities or bubbles. The first transparent layer 56a and the second transparent layer 56b, stacked onto the first transparent layer 56a, can be hence formed more suitably for an LED bare chip being the light emitter 52 than for an LED package being the light emitter 52

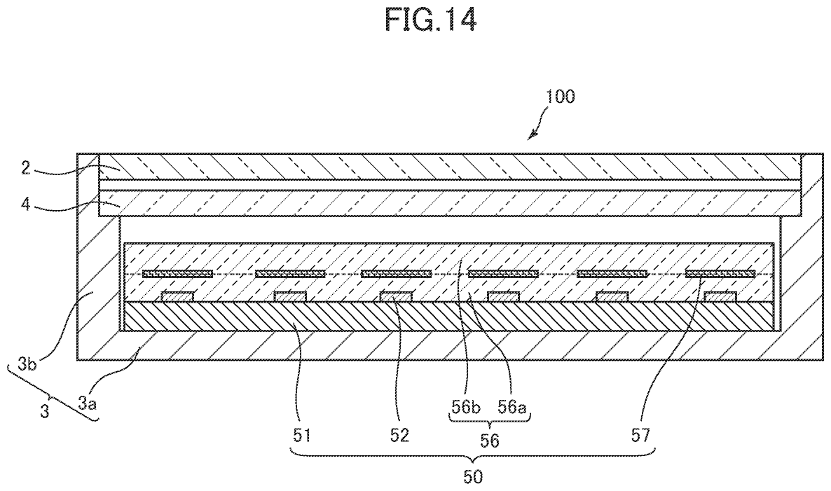

The frame 3 of the backlight 100 retains the optical sheet 2 at the distal end of the sidewall 3b, as earlier described. In some preferred embodiments, the frame 3 may further retain a fluorescent sheet 4 upstream of the optical sheet 2 in the direction of light exit in the backlight 100, as illustrated in FIG. 14. FIG. 14 is a sectional view of a modified version of the backlight 100 according to the first preferred embodiment of the present disclosure.

The fluorescent sheet 4 absorbs a particular wavelength of light emitted by each light emitter 52, while it emits a color of light complementing the color of the particular wavelength of light. That is, the fluorescent sheet 4 is provided for changing emitted light into white. For instance, when the light emitters 52 are LED bare chips that emit blue light, the fluorescent sheet 4 can be composed of a yellow-light fluorescent material dispersed in resin or other things.

Alternatively, the fluorescent sheet 4 may be composed of a green-light fluorescent material dispersed in resin or other things, and of a red-light fluorescent material dispersed in the resin or other things. An example of the fluorescent sheet 4 is a quantum-dot enhancement film (DEF) made by 3M. The fluorescent sheet 4 does not necessarily have to be provided when the light emitters 52 are LED bare chips that emit respective colors: R, G and B, or when there is any other way to change light into white.

### Second Preferred Embodiment

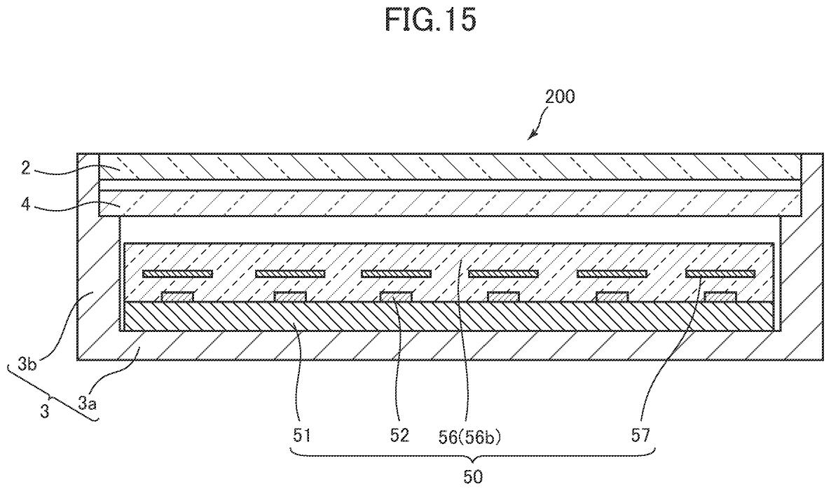

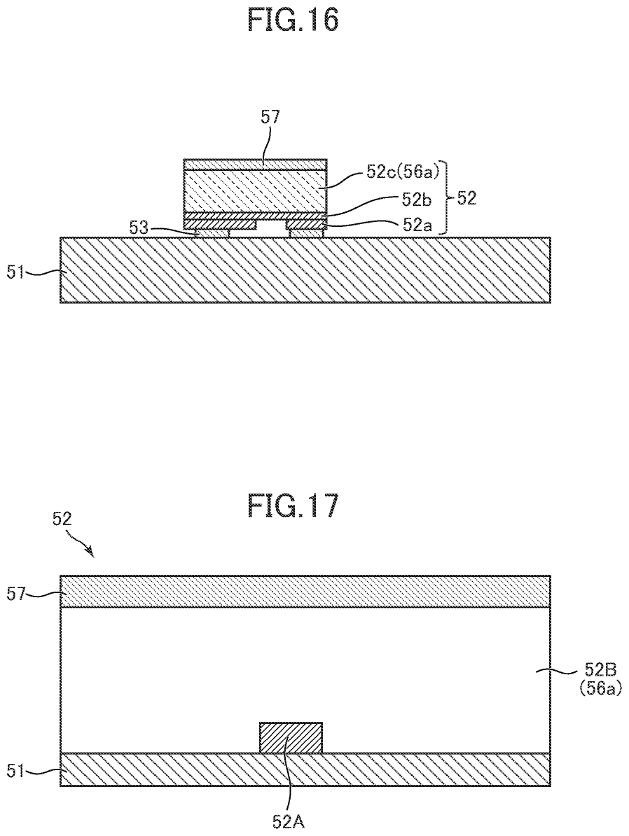

A backlight 200 according to a second preferred embodiment of the present disclosure will be described with reference to FIGS. 15 and 16. FIG. 15 is a sectional view of an example of the backlight 200 according to the second preferred embodiment of the present disclosure. FIG. 15 is a sectional view of the backlight 20( )cut in a location similar to the location where backlight 100 according to the first preferred embodiment is cut. FIG. 16 schematically illustrates an example configuration of the light emitter 52 mounted on the light-emitter-mounted substrate 50 included in the backlight 200 according to the second preferred embodiment of the present disclosure. FIG. 16 is a sectional view of the light emitter 52 that is an LED bare chip.

The backlight 100 according to the first preferred embodiment is configured such that the first transparent layer 56a covers the plurality of light emitters 52 on the circuit board 51. The backlight 100 is also configured such that the second transparent layer 56b covers the plurality of reflectors 57 on the first transparent layer 56a. In contrast, the backlight 200 according to the second preferred embodiment is different in that each light emitter 52 is an LED bare chip, and that the first transparent layer 56a is substituted by a transparent substrate 52c of each LED bare chip. The backlight 200 is also different in that the second transparent layer 56b covers the light emitters 52 and the reflectors 57.

To be specific, each light emitter 52 in the backlight 200 according to the second preferred embodiment is an LED bare chip that includes, as the first transparent layer 56a, the transparent substrate 52c having a main surface on which the emission part 52b and the electrode 52a are disposed. Furthermore, the electrode 52a is in direct contact with the circuit board 51 to establish electrical connection. That is, the light emitters 52 are mounted onto the circuit board 51 through flip-chip mounting, as illustrated in FIG. 3.

Each reflector 57 is disposed on a surface opposite to the main surface of the transparent substrate 52c. That is, since each light emitter 52 in the backlight 200 according to the second preferred embodiment is mounted onto the circuit board 51 through flip-chip mounting, the surface opposite to the main surface of the transparent substrate 52c is the upper surface of the light emitter 52. The reflector 57 is disposed on the surface (i.e., the upper surface) opposite to the main surface of the transparent substrate 52c.

As described, the backlight 200 according to the second preferred embodiment is configured such that the transparent substrate 52c of the light emitter 52 serves as the first transparent layer 56a, and such that the reflector 57 is disposed on the transparent substrate 52c, as illustrated in FIG. 16. In addition, the second transparent layer 56b covers the light emitters 52 and the reflectors 57, disposed on the upper surfaces of the respective light emitters 52, as illustrated in FIG. 15.

The second transparent layer 56b is made of a transparent resin having a refractive index equal to or higher than the refractive index of the transparent substrate 52c. That is, when the transparent substrate 52c is a sapphire substrate, the second transparent layer 56b is made of a transparent resin having a refractive index equal to or higher than the refractive index of the sapphire substrate. Achieving a high-refractive-index transparent resin requires introducing an aromatic ring, a halogen atom (excluding fluorine), or a sulfur atom into the chemical structure of a transparent resin.

In the backlight 200 having the foregoing configuration, light emitted by the emission part 52b of the light emitter 52 (LED bare chip) passes through the transparent substrate 52c and reflects on the reflector 57, which is disposed on the transparent substrate 52c. The light reflected on the reflector 57 passes through the transparent substrate 52c and is guided to the second transparent layer 56b. The light guided to the second transparent layer 56b reflects on the circuit board 51 again, then passes through the second transparent layer 56b, and then goes outside. Here, since the second transparent layer 56b covers the reflector 57, light emitted by the emission part 52b can be guided above the reflector 57 through the second transparent layer 56b. The backlight 200 according to the second preferred embodiment can consequently prevent brightness unevenness in its emission surface.

The light-emitter-mounted substrate 50 according to the second preferred embodiment includes the light emitters 52, each of which is an LED bare chip (light-emitter bare chip). The light-emitter-mounted substrate 50 according to a modification of the second preferred embodiment may include the light emitters 52 each of which is an LED package (light-emitter package) instead of an LED bare chip. That is, each light emitter 52 includes an LED bare chip 52A mounted on the circuit board 51, and includes a transparent sealing layer 52B covering and sealing the LED bare chip 52A on the circuit board 51, as illustrated in FIG. 17. FIG. 17 schematically illustrates an example configuration of the light emitter 52 mounted on the light-emitter-mounted substrate 50, included in the backlight 200 according to the modification of the second preferred embodiment of the present disclosure.

In the light emitter 52 (LED package) according to the modification of the second preferred embodiment of the present disclosure, the LED bare chip 52A is mounted on the circuit board 51 through flip-chip mounting. The LED bare chip 52A on the circuit board 51 is sealed by the transparent sealing layer 52B. The transparent sealing layer 52B can be a transparent resin having light transparency and low light-absorbing capability, such as acrylic resin, epoxy resin, silicone resin, or urethane resin. In the light-emitter-mounted substrate 50 according to the modification of the second preferred embodiment, the transparent sealing layer 528 serves as the first transparent layer 56a.

In the light-emitter-mounted substrate 50 according to the modification of the second preferred embodiment, each reflector 57 is formed onto the transparent sealing layer 52B through evaporation or plating and other methods. The reflector 57 is formed in the LED package in this way. This tight-emitter-mounted substrate 50 includes the second transparent layer 56b covering, on the circuit board 51, a plurality of LED packages provided with the reflectors 57.

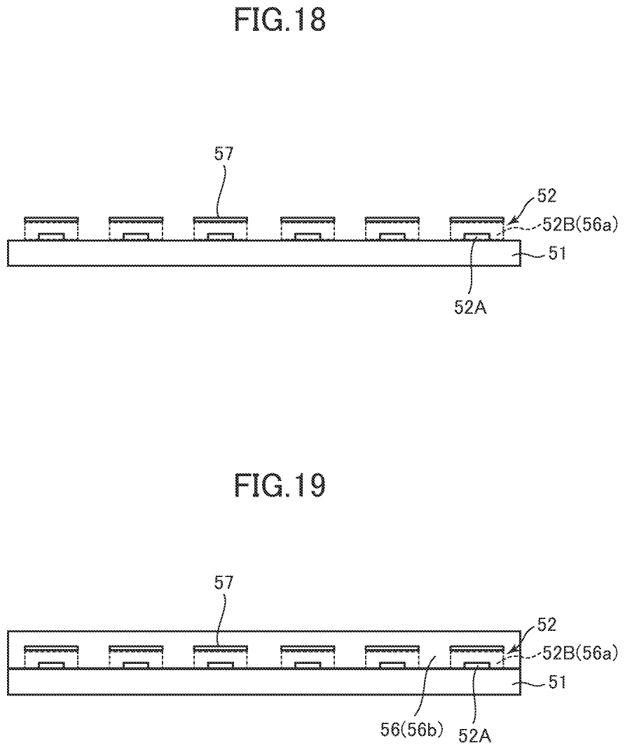

Such an LED package as the light emitter 52 can simplify process steps for forming the light-emitter-mounted substrate 50, as illustrated in FIGS. 18 and 19. FIGS. 18 and 19 schematically illustrate example process steps for forming the light-emitter-mounted substrate 50 of the backlight 200 according to the modification of the second preferred embodiment of the present disclosure.

Firstly, the light emitters 52 (LED packages) with the reflectors 57 on their upper surfaces are arranged in matrix onto the circuit board 51 at predetermined intervals, as illustrated in FIG. 18. Then, the electrodes of the LED bare chips 52A and the circuit board 51 are soldered to mount the light emitters 52 (LED packages) onto the circuit board 51. Mounting the light emitters 52 (LED packages) with the reflectors 57 thereon onto the circuit board 51 is followed by a process step illustrated in FIG. 19, where the second transparent layer 56b is formed onto the circuit board 51 so as to cover the reflectors 57 and light emitters 52 (LED packages). The second transparent layer is formed through, for instance, slit coating, screen printing, or inkjet printing.

Using the LED package as the light emitter 52 and using the transparent sealing layer 52B of the LED package as the first transparent layer 56a can omit a process step of forming the first transparent layer 56a. Consequently, the backlight 200 according to the modification of the second preferred embodiment can simplify process steps for forming the light-emitter-mounted substrate 50.

### Third Preferred Embodiment

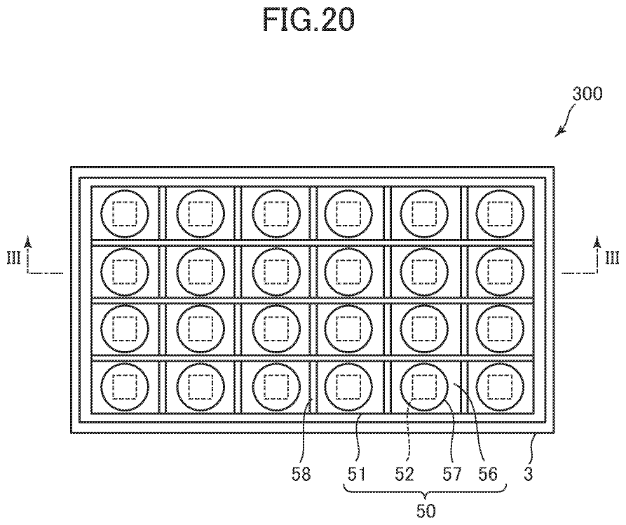

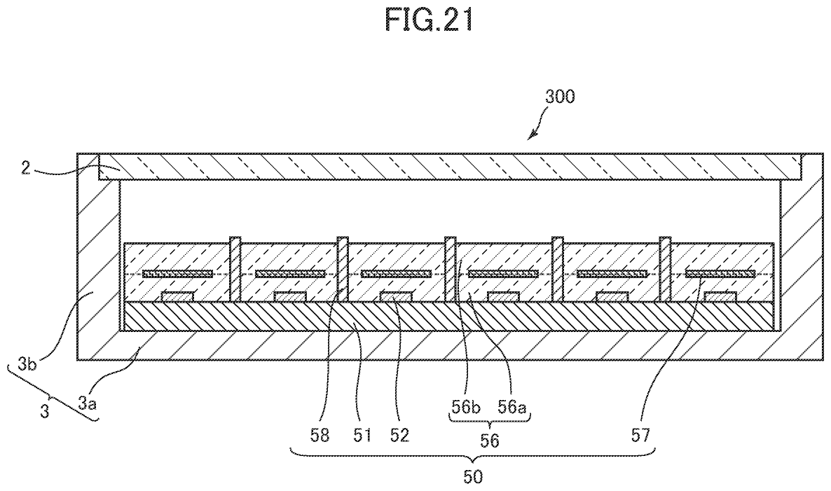

A backlight 300 according to a third preferred embodiment will be described with reference to FIGS. 20 and 21, FIG. 20 is a schematic plan view of an example configuration of the backlight 300 according to the third preferred embodiment. FIG. 21 is a sectional view of the backlight 300 according to the third preferred embodiment, taken along line

The backlight 300 according to the third preferred embodiment is different from the backlight 100 according to the first preferred embodiment in that the backlight 300 has a partition wall 58 surrounding each light emitter 52 on the circuit board 51. The backlight 300 according to the third preferred embodiment is similar to the backlight 100 according to the first preferred embodiment with the exception of the foregoing difference.

As illustrated in FIG. 20, the plurality of light emitters 52 are arranged in matrix on the circuit board 51 at predetermined intervals in a plan view of the light-emitter-mounted substrate 50. Furthermore, the partition wall 58 surrounds each light emitter 52 in the form of a lattice on the circuit board 51. Each light emitter 52 may be an LED bare chip or an LED package.

The partition wall 58 separates one pair of the light emitter 52 and reflector 57 covered by the transparent layer 56 from another pair of the light emitter 52 and reflector 57 covered by the transparent layer 56, as illustrated in FIG. 21. Here, one pair of the light emitter 52 and reflector 57 consists of the light emitter 52 and reflector 57 in a pair overlapping each other in a plan view of the light-emitter-mounted substrate 50.

The partition wall 58 is made of a high-reflectivity material and can thus reflect light. The partition wall 58 can be formed by applying white resin to a designated location using a dispenser (quantitative-liquid discharging device), an ink-jet printer, or other devices. Alternatively, a separate, injected molded object of white resin may be placed.

As described, the backlight 300 according to the third preferred embodiment is configured such that the light-emitter-mounted substrate 50 includes the partition wall 58, which surrounds each light emitter 52. This configuration enables the partition wall 58 to reflect light emitted by the light emitters 52. This configuration also enables the light reflected on the partition wall 58 to be guided above the reflectors 57 through the transparent layer 56.

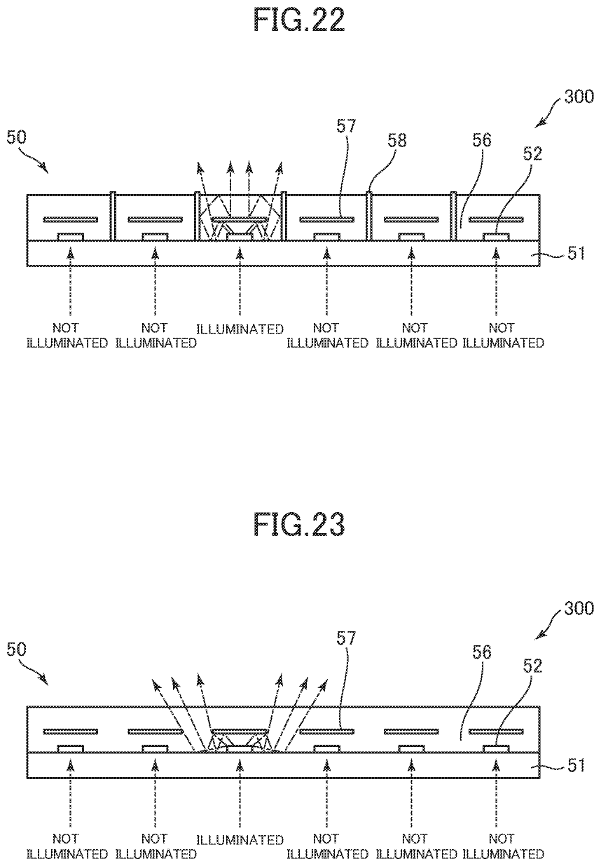

Specifically, with reference to FIGS. 22 and 23, the following describes the difference in the optical path of light emitted by each light emitter 52 between the light-emitter-mounted substrate 50 with the partition wall 58 and the light-emitter-mounted substrate 50 without the partition wall 58. FIG. 22 schematically illustrates an example optical path in the light-emitter-mounted substrate 50, included in the backlight 300 according to the third preferred embodiment. FIG. 23 schematically illustrates an example optical path in a light-emitter-mounted substrate included in a backlight according to a comparative example of the third preferred embodiment. FIGS. 22 and 23 illustrate an instance where only one light emitter 52 emits light. That is, the backlight 300 according to the third preferred embodiment is a direct-lit backlight. Thus, a liquid crystal display with the backlight 300 on its backside can perform local dimming, where light emitted by each light emitter 52 is regulated in accordance with differences in the local brightness of an image to be displayed on the liquid crystal panel. In FIGS. 22 and 23, the optical path of light emitted from the light emitter 52 is denoted by dot-dashed lines.

Let only any one of the light emitters 52 emit light; accordingly, in the backlight 300 according to the third preferred embodiment, light travels as illustrated in FIG. 22 and goes outside. That is, a part of light emitted by this light emitter 52 travels to the reflector 57. The light traveling to the reflector 57 reflects on the lower surface of the reflector 57 and then further reflects on the circuit board 51. The light reflected on the circuit board 51 passes through the transparent layer 56 and then goes outside the backlight 300. That is, light can exit from around the light emitter 52 to the outside.

Another part of the light reflects on the lower surface of the reflector 57, then further reflects on the circuit board 51 and partition wall 58, and then passes through the transparent layer 56 to reach a location above the reflector .57. A part of the light reaching the location above the reflector 57 reflects on the interface between the transparent layer 56 and air to travel to the upper surface of the reflector 57. The light traveling to the reflector 57 reflects on the upper surface of the reflector 57 and goes outside the backlight 300. That is, light can exit from above the reflector 57, which is located immediately above the light emitter 52, toward the outside.

The backlight 300 can consequently prevent brightness unevenness in its emission surface even when only one light emitter 52 emits light.

In the backlight 300 without the partition wall 58 by contrast, light emitted by only any one of the light emitters 52 travels as illustrated in FIG. 23 and goes outside. That is, light emitted by this light emitter 52 travels to the reflector 57. The light traveling to the reflector 57 reflects on the lower surface of the reflector 57 and then further reflects on the circuit board 51. The light reflected on the circuit board 51 passes through the transparent layer 56 disposed between the light emitter 52 and another adjacent light emitter .52, and then goes outside the backlight 300. That is, light emitted by the light emitter 52 can exit from around the light emitter 52 to the outside, but the amount of light exiting from above the reflector 57, which is immediately above the light emitter 52, to the outside is small. Hence, the backlight according to the comparative example of the third preferred embodiment possibly has brightness unevenness in its emission surface.

The backlight 300 according to the third preferred embodiment can prevent brightness unevenness in its emission surface even when it performs local dimming to individually regulate the amount of light emitted from the light emitters 52.

The foregoing has described that the partition wall 58 separates one pair of the light emitter 52 and reflector 57 from another pair of the light emitter 52 and reflector 57. In some preferred embodiments, the partition wall 58 may individually surround only the light emitters 52 as long as it can reflect light reflected on the lower surfaces of the reflectors 57 so as to guide the light above the reflectors 57.

While there have been described what are at present considered to be certain embodiments of the application, it will be understood that various modifications may be made thereto, and it is intended that the appended claim cover all such modifications as fall within the true spirit and scope of the application.

What is claimed is:

1. A light-emitter-mounted substrate comprising:
a circuit board;
a light emitter disposed on the circuit board, the light emitter having an electrode and an emission part, the electrode being electrically connected to the circuit board, the emission part being configured to emit light in accordance with a voltage applied via the electrode;
a reflector facing an emission surface of the emission part, the reflector being configured to reflect the light emitted from the emission part;
a transparent layer covering the light emitter and the reflector on the circuit board, the transparent layer having light transparency.

2. The light-emitter-mounted substrate according to claim 1, wherein
the transparent layer includes
a first transparent layer covering the light emitter, and
a second transparent layer disposed on the first transparent layer and covering the reflector.

3. The light-emitter-mounted substrate according to claim 2, wherein
the light emitter is a light-emitter package including a transparent sealing layer sealing the emission part, the transparent sealing layer being the first transparent layer,
the reflector is disposed on the light-emitter package, and
the second transparent layer covers the light-emitter package and the reflector on the circuit board.

4. The light-emitter-mounted substrate according to claim 2, wherein
the light emitter is a light-emitter bare chip with the electrode being in contact with the circuit board to establish electrical connection, the light-emitter bare chip including a transparent substrate having a main surface on which the emission part and the electrode are disposed, the transparent substrate being the first transparent layer,
the reflector is disposed on a surface opposite to the main face of the transparent substrate, and
the second transparent layer covers the light-emitter bare chip and the reflector on the circuit board.

5. The light-emitter-mounted substrate according to claim 2, wherein
the second transparent layer has a refractive index equal to or higher than a refractive index of the first transparent layer.

6. The light-emitter-mounted substrate according to claim 1, comprising
a partition wall surrounding the light emitter on the circuit board in a plan view of the tight-emitter-mounted substrate,
wherein the partition wall is composed of a high-reflectivity member.

7. The light-emitter-mounted substrate according to claim 1, wherein
the reflector overlaps the light emitter in a plan view of the light-emitter-mounted substrate, and
a diagonal line of a planar shape of the reflector has a length ranging from L to 10L inclusive, where L is a length of a diagonal line of a planar shape of the light emitter,

8. The light-emitter-mounted substrate according to claim 7, wherein
the planar shape of each of the light emitter and the reflector is rectangular or circular in the plan view of the light-emitter-mounted substrate.

9. The light-emitter-mounted substrate according to claim 8, wherein
the planar shape of the light emitter is rectangular, and
the planar shape of the reflector is circular,

10. The light-emitter-mounted substrate according to claim 8, wherein
the planar shape of each of the light emitter and the reflector is rectangular.

11. The light-emitter-mounted substrate according to claim 8, wherein
the planar shape of the light emitter and the planar shape of the reflector are similar.

12. The light-emitter-mounted substrate according to claim 1, wherein
the transparent layer is thicker than the light emitter, and is 10 times or less as thick as the light emitter.

13. A backlight comprising:
the light-emitter-mounted substrate according to claim 1;
a frame having
a bottom surface on which the light-emitter-mounted substrate is disposed, and
a sidewall surrounding the light-emitter-mounted substrate around a perimeter of the bottom surface; and
an optical sheet retained by the sidewall, the optical sheet being configured to change the light emitted from the emission part into a planar light source.
